(19) United States
(12) Patent Application Publication
(10) Pub. No.: US 2007/0139887 A1
(43) Pub. Date: Jun. 21, 2007

(54) Portable projector using an LED and related heat dissipating system

(75) Inventors: Wen-Tsung Lee, Hsinchu (TW); Ching-Chung Nien, Hsinchu (TW); Chih-Hao Chang, Hsinchu (TW)

Correspondence Address: BACON & THOMAS, PLLC, 625 SLATERS LANE, FOURTH FLOOR, ALEXANDRIA, VA, 22314, US

(73) Assignee: PREMIER IMAGE TECHNOLOGY CORPORATION, Taipei (TW)

(21) Appl. No.: 11/527,633

(22) Filed: Sep. 27, 2006

(30) Foreign Application Priority Data
Dec. 21, 2005 (TW) 094145531

(51) Int. Cl. H05K 7/20

(52) U.S. Cl. 361/700

(57) ABSTRACT

A portable projector with heat dissipating system is disclosed. The portable projector has a housing, at least a light source and a heat dissipating system, which comprises a heat dissipating tunnel, a light source heat dissipating module, and a fan. The heat dissipating tunnel has an inlet and an outlet such that air is able to enter the portable projector through the inlet and exit from it through the outlet. The light source heat dissipating module has at least one heat sink coupled to each light source for dissipating heat generated by each light source, and a heat pipe coupled to each heat sink for collecting heat dissipated by each heat sink to the heat dissipating tunnel, and the fan is located at the outlet of the heat dissipating tunnel for dissipating heat collected by the heat dissipating tunnel to the outside of the housing of the portable projector.

### BACKGROUND OF THE INVENTION

1. Field of the Invention

The present invention relates to a portable projector and, more particularly, to a portable projector that uses light emitting diodes (LEDs) and a related heat dissipating system.

2. Description of the Related Art

Since projectors have become increasingly popular, the requirements of portable projectors have grown too. Projectors are high precision opto-mechatronics products; their components are highly temperature sensitive, and have a very complicated layout. Consequently, the cooling capabilities of the projector are very important. In particular, improving cooling capabilities without increasing either the size or noise characteristics of the projector is of interest.

Generally, the prior art projector requires a very high brightness, and so needs a high power light source. Therefore, after a long period of operation, the light source invariably generates large amounts of heat within the projector. In addition to the heat generated by the light source, the power supply and imaging system of the projector also generate heat during the operation. Furthermore, the heat generated by the light source, the imaging system, and the power supply all collect in the projector, which leads to high temperatures that affect the operations of the projector and reduces the lift times of other elements.

Prior art projectors usually utilize multiple cooling fans to reduce temperatures. However, cooling fans increase the size of the projector. Furthermore, the noise caused by cooling fans is another problem for the projector.

Therefore, it is desirable to provide a portable projector and a related heat dissipating system to mitigate and/or obviate the aforementioned problems.

### SUMMARY OF THE INVENTION

The present invention provides a portable projector using LED and its heat dissipating system to mitigate and/or obviate the aforementioned problems.

The portable projector of the present invention comprises: a housing, at least one light source and a heat dissipating system. Each one of the at least one light source is LED. The heat dissipating system comprises a heat dissipating tunnel, a light source heat dissipating module, and a fan.

The heat dissipating tunnel has an inlet and an outlet such that air is able to enter the portable projector through the inlet and exit from it through the outlet. The light source heat dissipating module comprises: at least one heat sink coupled to each light source for dissipating heat generated by each light source, and a heat pipe coupled to each heat sink for collecting heat dissipated by each heat sink to the heat dissipating tunnel. The fan is located at the outlet of the heat dissipating tunnel for dissipating heat collected by the heat dissipating tunnel to the outside of the housing of the portable projector.

The present invention also provides a portable projector with low power light source, which only utilizes one fan.

In one preferred embodiment, the housing is made of a highly thermally conductive material and contacts one of the at least one heat sink, and the heat is collected at the heat pipe so the heat can be dissipated outside of the portable projector via the housing.

The present invention also provides a portable projector with low power light source, which needs no fan.

In one preferred embodiment, heat dissipating system further comprises at least one thermal pad; each thermal pad is disposed between each light source and each heat sink. Alternatively, the heat dissipating system further comprises at least one heat transfer compound; each heat transfer compound coated between each light source and each heat sink.

Furthermore, in one preferred embodiment, the housing of the portable projector is made of a highly thermally conductive material, such as aluminum or an aluminum magnesium alloy; the at least one heat sink is made of aluminum or copper; and the at least one heat pipe is made of stainless steel or copper.

Furthermore, in one preferred embodiment, the at least one heat sink is disposed in the heat dissipating tunnel so air can enter from the inlet, pass through gaps among the plurality of fins, and transmit the heat dissipated by the at least one heat sink to the outlet so the heat is removed from the portable projector by the fan.

Other objects, advantages, and novel features of the invention will become more apparent from the following detailed description when taken in conjunction with the accompanying drawings.

### BRIEF DESCRIPTION OF THE DRAWINGS

FIG. 1 is an internal layout schematic drawing of a portable projector according to the present invention.

FIG. 2A is a layout schematic of a light source heat dissipating module of an embodiment according to the present invention.

FIG. 2B is a layout schematic of a light source heat dissipating module of another embodiment according to the present invention.

### DETAILED DESCRIPTION OF THE PREFERRED EMBODIMENT

As mentioned above, for small portable projectors, adding additional fans in the heat dissipating system increases the noise, dust, and power requirements, as well as the size of the projector.

Therefore, the present invention provides a portable projector with one fan, or even no fan, and this is especially the case for portable projectors using LEDs as a light source. Since LEDs do not generate too much heat, there is no necessity for multiple fans.

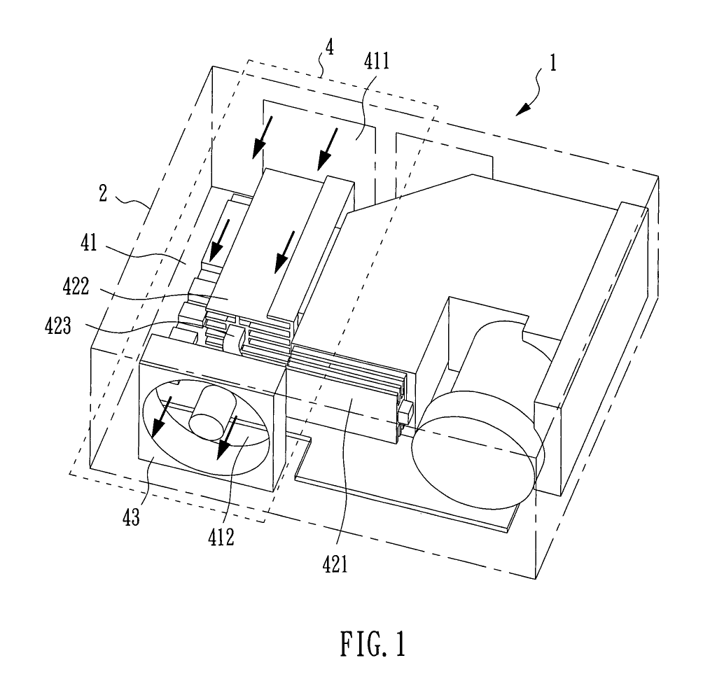

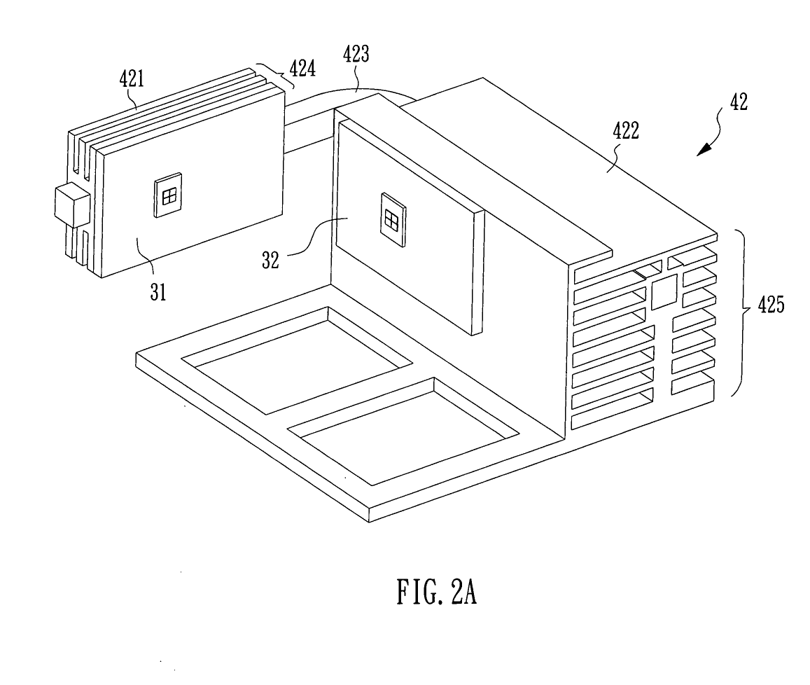

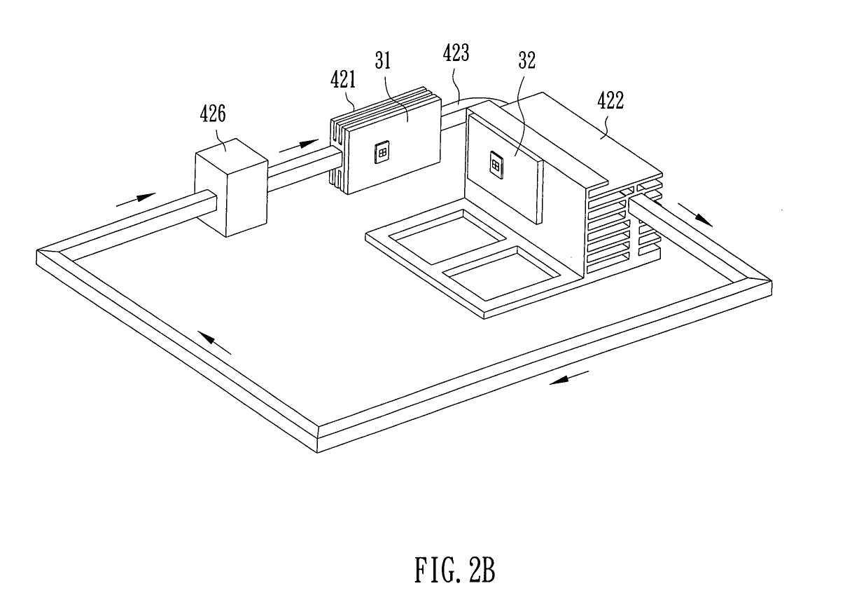

Please refer to FIG. 1 and FIG. 2A. FIG. 1 is an internal layout schematic of a portable projector according to the present invention. FIG. 2A is a layout schematic of a light source heat dissipating module of an embodiment according to the present invention.

As shown in FIG. 1 and FIG. 2A, according to a first embodiment of the present invention, a portable projector 1 comprises a housing 2, two light sources 31, 32 and a heat dissipating system 4.

As shown in FIG. 1 and FIG. 2A, the light sources 31, 32 are placed in the housing 2 and used for providing light when the portable projector 1 is operating. The light sources 31, 32 are preferably LED devices, which can reduce the power consumption of the portable projector 1 and reduce the operating heat load. Although there are two light sources 31, 32 shown in FIG. 2A, this design should not be considered limiting to the present invention. The portable projector 1 can be operated with at least one light source; therefore, the present invention may utilize one light source, two light sources or more light sources.

As shown in FIG. 1, the heat dissipating system 4 is placed in the housing 2 and used for removing the heat generated by the light sources 31, 32, and the heat generated by other systems (such as the power supply or the imaging system) in the portable projector 1. The heat dissipating system 4 comprises a heat dissipating tunnel 41, a light source heat dissipating module 42 and a fan 43.

As shown in FIG. 1, the heat dissipating tunnel 41 has an inlet 411 and an outlet 412 and forms a tunnel between the inlet 411 and the outlet 412 so that air is able to enter the portable projector through the inlet 411 and exit it through the outlet 412, as shown by the arrows in FIG. 1.

As shown in FIG. 2A, the light source heat dissipating module 42 comprises two heat sinks 421, 422 and a heat pipe 423. The heat sinks 421, 422 are respectively coupled to the light sources 31, 32, and each heat sink 421, 422 has a plurality of fins 424, 425 for dissipating the heat generated by the light source 31, 32. Two ends of the heat pipe 423 are respectively coupled to the heat sinks 421, 422 and used for conducting the heat from the heat sinks 421, 422 so that the heat is collected at the heat dissipating tunnel 41 shown in FIG. 1. Although there are two heat sinks 421, 422 and one heat pipe 423 shown in FIG. 1 and FIG. 2A, this design should not be construed as limiting for the present invention. The portable projector 1 may have different numbers of heat sinks and heat pipes according to the number of the light sources and various designs.

As shown in FIG. 1, the fan 43 is placed at the outlet 412 of the heat dissipating tunnel 41 and used for removing both the heat collected at the heat dissipating tunnel 41 and the heat generated by other systems in the portable projector 1 to the outside of the housing 2 of the portable projector 1.

The present invention can cool multiple light sources and simplifies the heat dissipating system. With the high thermal conductivity of the heat pipe 423 and the heat sinks 421, 422, the heat generated by the light sources 31, 32 is dissipated and collected at the heat dissipating tunnel 41. Furthermore, the fan 43 placed at the outlet 412 of the heat dissipating tunnel 41 removes the heat collected at the heat dissipating tunnel 41 to the outside of the housing 2 of the portable projector 1.

In one embodiment, the housing 2 can be made of a highly thermally conductive material, such as aluminum, or an aluminum magnesium alloy; the heat sinks 421, 422 can be made of aluminum or copper; and the heat pipe 423 can be made of stainless steel or copper to increase the cooling efficiency of the portable projector 1. However, the housing 2, the heat sinks 421, 422, and the heat pipe 423 all can be made of other thermally conductive materials. Furthermore, the present invention may further comprise a thermal pad (not shown) and/or a heat transfer compound (not shown) coated respectively between the light sources 31, 32 and the heat sinks 421, 422 for better cooling efficiencies.

To achieve even better cooling efficiencies, the heat sink 422 may be placed in the heat dissipating tunnel 4. Therefore, air can enter from the inlet 411, pass through gaps among the plurality of fins 424 of the heat sink 422, and transmit the heat dissipated by the heat sink 422 to the outlet 412 and be removed from the portable projector 1 by the fan 43.

Please refer to FIG. 2B. FIG. 2B is a layout schematic of a light source heat dissipating module of another embodiment according to the present invention. As shown in FIG. 2B, in another embodiment, the light source heat dissipating module 42′ comprises two heat sinks 421′, 422′, a heat pipe 423′ and a pump 426.

The heat sink 421′ and 422′ are respectively connected to the light sources 31, 32, and at least one of the heat sinks 421′ and 422′ contacts the housing 2, as shown in FIG. 1. The heat pipe 423′ is filled with a fluid and coupled to each heat sink 421′ and 422′; the pump 426 is coupled to the heat pipe 423′ and is used to cause the fluid in the heat pipe 423′ to flow.

Accordingly, as shown in FIG. 2B, the present invention requires no fan; it utilizes the liquid-cooled heat pipe 423′ to collect heat at the heat sink contacting the housing 2, and the housing 2 removes the heat to the outside of the portable projector 1.

The portable projector of the present invention and its related heat dissipating system can minimize the number of fans used, but continues to provide heat dissipation and cooling to multiple light sources at the same time, and provides the following benefits:

1. reduced costs;

2. a simplified structure for the heat dissipating system;

3. reduced power consumption for the heat dissipating system, which is very useful for the portable projectors that use batteries;

4. reduced noise; and

5. reduced volume.

Although the present invention has been explained in relation to its preferred embodiment, it is to be understood that many other possible modifications and variations can be made without departing from the spirit and scope of the invention as hereinafter claimed.

What is claimed is:

1. A portable projector comprising:
a housing;
at least one light source located in the housing, each one of the at least one light source being an LED; and
a heat dissipating system located in the housing for dissipating heat generated by the at least one light source, the heat dissipating system comprising:
a heat dissipating tunnel having an inlet and an outlet such that air is able to enter the portable projector through the inlet and exit through the outlet;
a light source heat dissipating module comprising:
at least one heat sink, each one of the at least one heat sink coupled to a respective light source of the at least one light source, each heat sink having a plurality of fins, the at least one heat sink being used for dissipating heat generated by the respective light source; and
at least one heat pipe, each one of the at least one heat pipe coupled to a respective heat sink for transferring heat dissipated by each heat sink to the heat dissipating tunnel; and
a fan located at the outlet of the heat dissipating tunnel for removing heat collected by the heat dissipating tunnel to the outside of the housing of the portable projector.

2. The portable projector as claimed in claim 1, wherein the housing is made of a highly thermally conductive material.

3. The portable projector as claimed in claim 1, wherein the highly thermally conductive material is aluminum or an aluminum-magnesium alloy.

4. The portable projector as claimed in claim 1, wherein the heat dissipating system further comprises at least one thermal pad, each one of the at least one thermal pad is disposed between each light source and each heat sink.

5. The portable projector as claimed in claim 1, wherein the heat dissipating system further comprises at least one heat transfer compound, each one of the at least one heat transfer compound is coated between each light source and each heat sink.

6. The portable projector as claimed in claim 1, wherein the at least one heat sink is made of aluminum or copper.

7. The portable projector as claimed in claim 1, wherein the at least one heat pipe is made of stainless steel or copper.

8. The portable projector as claimed in claim 1, wherein the at least one heat sink is placed in the heat dissipating tunnel so air can enter from the inlet, pass through gaps among the plurality of fins, and transmit the heat dissipated by the at least one heat sink to the outlet so the heat is removed from the portable projector.

9. A portable projector comprising:
a housing;
at least one light source located in the housing, each one of the at least one light source being an LED; and
a heat dissipating system located in the housing for dissipating heat generated by the at least one light source, the heat dissipating system comprising:
a light source heat dissipating module comprising:
at least one heat sink, each one of the at least one heat sink coupled to a respective light source of the at least one light source, each heat sink having a plurality of fins, the at least one heat sink being used for dissipating heat generated by the at least one light source;
a heat pipe filled with a fluid, each one of the at least one heat pipe coupled to a respective heat sink for transferring heat dissipated by each heat sink to the heat dissipating tunnel; and
a pump coupled to the heat pipe for moving the fluid in the heat pipe so the fluid is able to flow in the heat pipe.

10. The portable projector as claimed in claim 9, wherein the housing is made of a highly thermally conductive material and contacts one of the at least one heat sink, and the heat is collected at the heat pipe so the heat can be dissipated outside of the portable projector via the housing.

11. The portable projector as claimed in claim 10, wherein the highly thermally conductive material is aluminum or an aluminum-magnesium alloy.

12. The portable projector as claimed in claim 9, wherein the heat dissipating system further comprises a heat dissipating tunnel, the heat dissipating tunnel having an inlet and an outlet such that air is able to enter the portable projector through the inlet and exit through the outlet.

13. The portable projector as claimed in claim 12, wherein the heat dissipating system further comprises a fan located at the outlet of the heat dissipating tunnel and is used for removing heat collected by the heat dissipating tunnel to the outside of the housing of the portable projector.

14. The portable projector as claimed in claim 13, wherein the at least one heat sink is disposed in the heat dissipating tunnel so air can enter from the inlet, pass through gaps among the plurality of fins, and transmit the heat dissipated by the at least one heat sink to the outlet so the heat is removed from the portable projector by the fan.

15. The portable projector as claimed in claim 9, wherein the heat dissipating system further comprises at least one thermal pad, each one of the at least one thermal pad is disposed between each light source and each heat sink.

16. The portable projector as claimed in claim 9, wherein the heat dissipating system further comprises at least one heat transfer compound, each one of the at least one heat transfer compound is coated between each light source and each heat sink.

17. The portable projector as claimed in claim 9, wherein each light source of the at least one light source is an LED.
